(19) United States
(12) Patent Application Publication
(10) Pub. No.: US 2025/0350050 A1
(43) Pub. Date: Nov. 13, 2025

(54) ROTATABLE HORIZONTAL POWER SOCKET FOR SERVERS

(71) Applicant: Aivres Systems Inc., San Jose, CA (US)

(72) Inventor: Yu Hsin SHEN, New Taipei City (TW)

(21) Appl. No.: 19/276,386

(22) Filed: Jul. 22, 2025

(51) Int. Cl. H01R 12/70; H01R 12/58; H01R 13/627; H01R 13/631; H01R 13/717; H01R 35/04; H01R 43/20; H05K 7/14

(52) U.S. Cl. CPC H01R 12/7076; H01R 12/58; H01R 12/707; H01R 12/7088; H01R 13/6275; H01R 13/631; H01R 13/7175; H01R 35/04; H01R 43/205; H05K 7/1492

(57) ABSTRACT

A rotatable power socket includes a base structure configured to be mounted on a printed circuit board (PCB), and a rotatable socket body coupled to the base structure and configured to rotate about an axis substantially perpendicular to the PCB. The socket body includes a socket interface for receiving an external power plug inserted along a direction substantially parallel to the surface of the PCB. A rotational locking assembly is positioned between the base structure and the socket body to provide discrete rotational positions. A plug retention mechanism is included to secure the external power plug after insertion. The socket may further include plug alignment features and an LED indicator for visual connection status.

### TECHNICAL FIELD

The present disclosure relates to power connectors and socket modules used in electronic systems, and more particularly to a rotatable, side-insertion power socket module for printed circuit boards (PCBs) in servers.

### BACKGROUND

Modern computing systems such as high-performance computing (HPC) clusters, artificial intelligence (AI) servers, and edge computing modules require compact and efficient power delivery solutions. As these platforms increasingly adopt modular architectures and higher power densities, the physical layout and connectivity of power interfaces become critical to overall system reliability, airflow efficiency, and serviceability.

Conventional power socket designs typically involve vertical plug-in orientations, with the socket mounted on a chassis or metal frame and the plug inserted externally. This structure often limits spatial flexibility, obstructs vertical clearance above the motherboard or PCB, and complicates internal cable routing. Additionally, such configurations are prone to cable interference, difficult manual access during maintenance, and increased susceptibility to electrical noise.

These limitations are particularly problematic in low-profile, high-density environments such as 1U/2U servers, blade server enclosures, GPU compute clusters, and industrial control modules, where vertical space is scarce and precise cable management is essential.

There is a need in the industry for a compact, PCB-mountable power socket module that supports horizontal (side) insertion, ensures proper orientation through mechanical guidance, enables indexed rotational positioning to optimize cable routing, and incorporates locking mechanisms to ensure secure electrical and mechanical coupling.

The present invention addresses these needs by providing a rotatable, side-insertion power socket module with angular locking, anti-misplug features, and modular integration capabilities tailored to modern high-density electronic systems.

### SUMMARY

A system comprising one or more computers can be configured to perform specific operations or actions by virtue of having software, firmware, hardware, or a combination thereof installed on the system. This configuration, in operation, causes the system to perform the desired actions. One or more computer programs can also be configured to perform particular operations by including instructions that, when executed by data processing apparatus, cause the apparatus to perform the specified actions.

In one general aspect, a rotatable power socket may include a base structure configured to be mounted on a printed circuit board (PCB). The base structure may include a plurality of electrical terminals extending downward from its bottom surface for electrical connection to the PCB. The rotatable power socket may also include a rotatable socket body that is rotatably coupled to the base structure and configured to rotate relative to it about an axis substantially perpendicular to the PCB. The rotatable socket body may comprise a socket interface configured to receive an external power plug inserted along a direction substantially parallel to the surface of the PCB, and a plug retention assembly configured to retain the external power plug after insertion. The socket may further include a rotational locking assembly disposed between the base structure and the rotatable socket body, configured to provide discrete rotational positions of the rotatable socket body relative to the base structure. Other embodiments of this aspect may include corresponding computer systems, apparatuses, and computer programs recorded on one or more computer storage devices, each configured to perform the actions of the described methods.

Implementations may include one or more of the following features. The rotational locking assembly may include a gear ring coupled to the rotatable socket body and having a plurality of detents spaced at uniform angular intervals. The detents may be spaced at 30-degree or 45-degree intervals to define the discrete rotational positions. The rotational locking assembly may further include a spring-loaded ball disposed in the base structure and biased toward the gear ring to engage the detents. The spring-loaded ball may be held in position by a fastener secured within the base structure. The plug retention assembly may include a sliding latch disposed on a lateral side of the base structure and configured to lock the external power plug upon insertion. The sliding latch may be manually disengaged by sliding it in a direction opposite to the plug insertion direction. An LED indicator may be disposed on an exterior surface of the rotatable socket body and configured to emit light in response to electrical engagement with the external power plug. One or more plug alignment structures may be disposed at or near the socket interface and configured to restrict the insertion orientation of the external power plug. The plug alignment structures may include one or more of an insertion guide surface, an anti-misplug groove, or a directional-restricting groove. The socket interface may be configured to receive a standardized AC power plug or a high-current DC power connector. The base structure may include an internal cable routing guide configured to electrically connect the socket interface to the electrical terminals. Implementations of the described techniques may be embodied in hardware, as a method or process, or as instructions stored on a tangible computer-readable medium.

In another general aspect, a power distribution system may include a printed circuit board (PCB) and a rotatable power socket mounted on the PCB. The rotatable power socket may include a base structure mounted to the PCB and having a plurality of electrical terminals extending into the PCB, a rotatable socket body coupled to the base structure and rotatable about an axis substantially perpendicular to the PCB, the socket body including a socket interface configured to receive a power plug inserted along a direction substantially parallel to the surface of the PCB, a rotational locking assembly configured to provide discrete rotational positions of the socket body relative to the base structure, and a plug retention assembly configured to retain the power plug after insertion. Other embodiments of this aspect may include corresponding computer systems, apparatuses, and computer programs recorded on one or more computer storage devices, each configured to perform the actions of the described methods.

Implementations may include one or more of the following features. The PCB may be part of a motherboard of a server. The plug retention assembly may include a sliding latch disposed on a lateral side of the base structure and configured to lock the power plug after insertion. The rotatable power socket may include an LED indicator disposed on the socket body and configured to emit light in response to engagement between the power plug and the electrical terminals of the rotatable power socket. Implementations of the described techniques may be embodied in hardware, as a method or process, or as instructions stored on a tangible computer-readable medium.

In another general aspect, the method may include providing a base structure configured to be mounted on a printed circuit board (PCB). The method may also include installing a plurality of electrical terminals extending downward from the bottom of the base structure for electrical connection to the PCB. Furthermore, the method may include assembling a rotatable socket body configured to rotate relative to the base structure about an axis substantially perpendicular to the PCB, and integrating a socket interface into the socket body. The socket interface is configured to receive a power plug inserted along a direction substantially parallel to the surface of the PCB. Other embodiments of this aspect may include corresponding computer systems, apparatuses, and computer programs recorded on one or more computer storage devices, each configured to perform the actions of the method.

Implementations may include one or more of the following features. The method may include assembling a rotational locking assembly between the base structure and the rotatable socket body, where the rotational locking assembly includes a gear ring with a plurality of detents spaced at uniform angular intervals, and a spring-loaded ball biased toward the gear ring and positioned to engage the detents. The method may include attaching a plug retention mechanism to a lateral surface of the base structure, the mechanism including a sliding latch configured to engage the power plug upon insertion. The method may also include installing an LED indicator on an exterior surface of the rotatable socket body and electrically coupling it to one or more of the electrical terminals for activation upon successful plug engagement. Implementations of the described techniques may be embodied in hardware, as a method or process, or as instructions stored on a tangible computer-readable medium.

### BRIEF DESCRIPTION OF THE DRAWINGS

FIG. 1 illustrates examples of conventional power plug types, including a C14 AC inlet and an 8-pin GPU power connector, both of which typically require vertical insertion into a chassis-mounted power socket.

FIG. 2 illustrates a perspective view of the rotatable horizontal power socket for PCB, in accordance with some embodiments.

FIG. 3A illustrates an exploded view of the rotatable horizontal power socket for PCB, in accordance with some embodiments.

FIG. 3B illustrates a cross-section view of the rotatable horizontal power socket for PCB, in accordance with some embodiments.

FIGS. 3C and 3D illustrate two additional perspective views of the rotatable horizontal power socket for PCB, in accordance with some embodiments.

FIG. 4 illustrates an example method for manufacturing the rotatable horizontal power socket for PCB, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

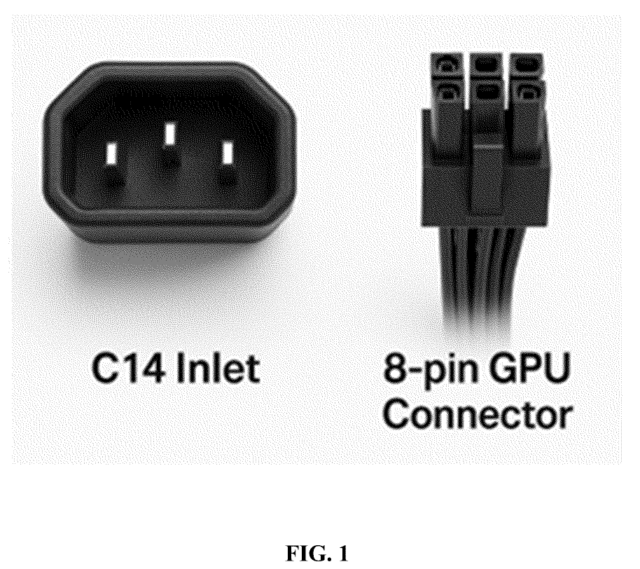

FIG. 1 illustrates examples of conventional power plug types, including a C14 AC inlet (left) and an 8-pin GPU power connector (right), both of which are commonly used in server systems, desktop computers, and high-performance computing equipment. These plug types are designed for vertical insertion into a corresponding chassis-mounted power socket, typically located on the rear or side panel of the enclosure.

In such traditional systems, the power socket is mounted on the chassis or metal frame, while the printed circuit board (PCB)—such as a motherboard, backplane, or power distribution board—is located inside the enclosure. Electrical power from the plug is routed through the chassis-mounted socket and connected to the PCB using internal power cables. These cables distribute current to downstream loads, including voltage regulators, CPUs, memory modules, GPUs, and other ICs mounted on the PCB.

While this chassis-mounted architecture is widely used, it presents multiple limitations—especially as server systems evolve toward thinner, denser, and more modular configurations. Vertically inserted plugs protrude inward into the system enclosure and occupy valuable space directly above the PCB, which could otherwise be used for airflow management, heat sinks, or additional component stacking. The use of long internal cables also increases complexity, creates cable routing challenges, and introduces electrical inefficiencies and potential EMI issues. Maintenance becomes more difficult, as replacing or reconfiguring such sockets often requires partial system disassembly.

These limitations are particularly problematic in high-density environments such as 1U/2U rack servers, blade server nodes, edge computing enclosures, and GPU clusters. These systems require low-profile, compact layouts with optimized thermal and mechanical design. Accordingly, a power socket that supports horizontal insertion—i.e., along a direction substantially parallel to the surface of the PCB—is better suited to these form factors. By mounting the socket directly onto the PCB and receiving the plug from the side, such a configuration avoids vertical obstruction and eliminates the need for intermediate wiring, simplifying assembly and improving airflow and spatial efficiency. As used in this disclosure, “substantially parallel” indicates that the direction of movement or alignment is generally in the same plane as a reference surface or axis, including small angular deviations (e.g., within ±15 degrees) that do not interfere with the intended low-profile or side-access design of the system. Similarly, “substantially perpendicular” refers to orientations that are generally orthogonal to a reference surface or axis, allowing for minor angular deviations (e.g., within ±15 degrees) that do not affect the functional alignment or engagement of the components.

In addition, the rotatable power socket described in the present disclosure introduces a rotatable socket body that allows the installer to adjust the plug orientation after insertion. Through a rotational locking assembly that provides discrete angular positions (e.g., every 30 or 45 degrees), the socket can be tuned to accommodate specific cable routing paths within the system enclosure. This flexibility is particularly beneficial in data centers and OEM designs where space constraints, airflow zones, and adjacent components vary from system to system. The combination of horizontal insertion and indexed rotational adjustment enables a compact, adaptable, and serviceable power delivery interface tailored to modern computing infrastructure.

In the following figures, reference numerals are used consistently to identify structural elements of the rotatable power socket. The reference numerals and their corresponding component names are listed below:

| Reference Label | Component Name |
|---|---|
| 10 | Rotatable socket body |
| 11 | Base structure |
| 13 | Solder pins |
| 20 | Plug |
| 21 | Insertion guide interface |
| 22 | Anti-misplug groove |
| 23 | Orientation-limiting gear |
| 31 | Gear ring (with detents) |
| 32 | Spring-loaded ball |
| 33 | Compression spring |
| 34 | Fixing screw |
| 41 | Sliding latch mechanism |
| 60 | Printed circuit board (PCB) |
| 61 | Cable routing track |
| 62 | Power cable |
| 70 | LED indicator |
| 200 | Rotatable power socket |

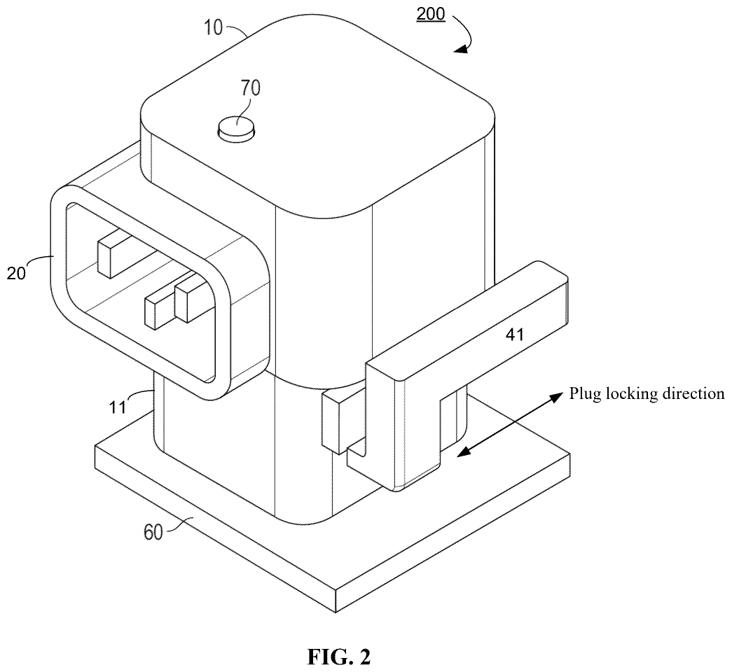

FIG. 2 illustrates a perspective view of a rotatable power socket 200 mounted on a printed circuit board (PCB) 60, according to some embodiments of the present disclosure. In these embodiments, the PCB 60 may be a motherboard, backplane, or another type of printed circuit substrate used in high-density computing systems. As used herein, the term “motherboard” is not limited to traditional motherboards found in standard computer systems, but broadly includes various types of PCBs deployed in dense electronic platforms. These may include, but are not limited to, server backplanes, power distribution boards, communication equipment baseboards, and control boards for AI computing modules. The rotatable power socket module may be directly soldered to or mechanically fastened onto such PCBs for deployment.

In the embodiment illustrated in FIG. 2, the rotatable power socket 200 includes two main structural components: a fixed base structure 11 and a rotatable socket body 10 disposed on top of the fixed base structure 11. The base structure 11 is mechanically secured to the PCB 60 and includes a plurality of electrical terminals (not visible in FIG. 2) extending downward from its bottom surface, configured for electrical and mechanical connection to the PCB 60. The base structure 11 provides stable mechanical support for the overall socket, while also facilitating the transmission of electrical power received from an external plug to circuitry and components on the PCB.

The rotatable socket body 10 is coupled to the base structure 11 in a manner that allows the rotatable socket body 10 to rotate relative to the base structure 11 about an axis substantially perpendicular to the surface of the PCB 60. A socket interface 20 is formed on a front face of the rotatable socket body 10, facing outward and configured to receive an external power plug (not shown in FIG. 2). The socket interface 20 is oriented such that the external power plug can be inserted horizontally, or substantially parallel to the PCB 60, to optimize the use of limited vertical space within a chassis or enclosure. In some embodiments, the socket interface 20 can be adapted or configured to support specific plug types, such as a standardized AC inlet (e.g., C14 type) or a high-current DC connector (e.g., GPU 8-pin plug).

Disposed on a lateral side of the base structure 11 is a plug retention assembly 41, illustrated as a sliding latch. In some embodiments, the sliding latch 41 is integrated into the base structure 11 and is configured to automatically engage with the external power plug when it is fully inserted. For example, the plug retention assembly 41 includes a spring-loaded cam or catch mechanism that permits the plug to slide past the latch during insertion. Once the plug reaches its fully inserted position, the spring bias causes the latch of the plug retention assembly 41 to snap into a retention groove or recess formed on the external power plug, thereby mechanically securing the plug in place. This prevents accidental disconnection due to vibration, mechanical stress, or incidental contact. In some embodiments, to remove the plug, a user may manually slide the latch outward or downward, in a direction opposite to the plug locking direction, to disengage the catch from the retention groove.

In some embodiments, an LED indicator 70 is provided on an exterior surface, such as the top surface (as shown in FIG. 2) or the side surface, of the rotatable socket body 10. This LED indicator 70 serves as a visual confirmation of successful electrical engagement between the external power plug and the internal socket contacts. In some implementations, activation of the LED indicator 70 occurs upon detecting electrical connection, mechanical locking engagement of the plug, or a combination thereof.

Internally, the rotatable power socket 200 includes a rotational locking assembly (not visible in FIG. 2) positioned within or across the base structure 11 and the rotatable socket body 10. This rotational locking assembly enables selective rotation of the rotatable socket body 10 relative to the base structure 11 and secures it at discrete rotational positions. This rotational capability provides flexibility in plug orientation and cable routing, thereby accommodating various system configurations and cable management strategies. Additional details of the rotational locking assembly and its internal components will be described further with reference to subsequent figures.

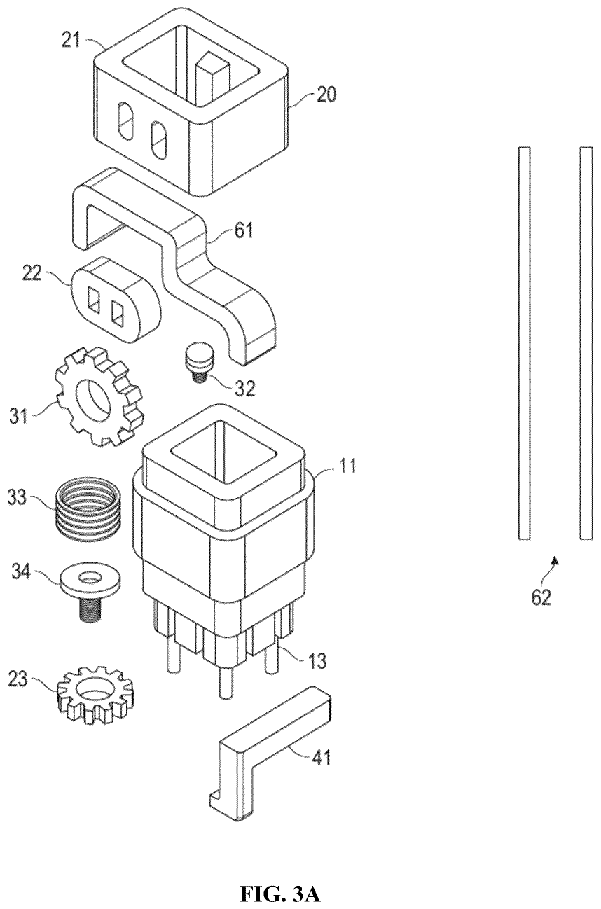

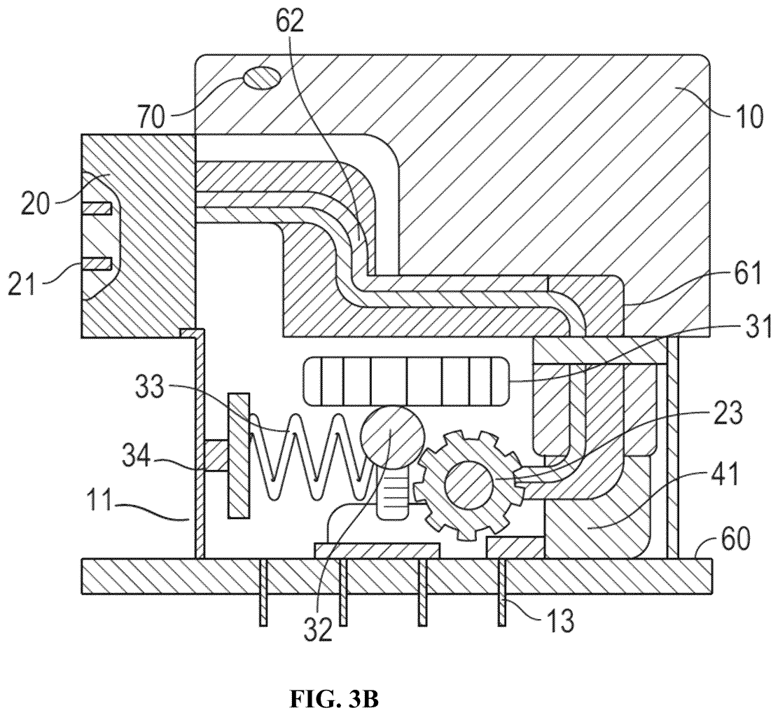

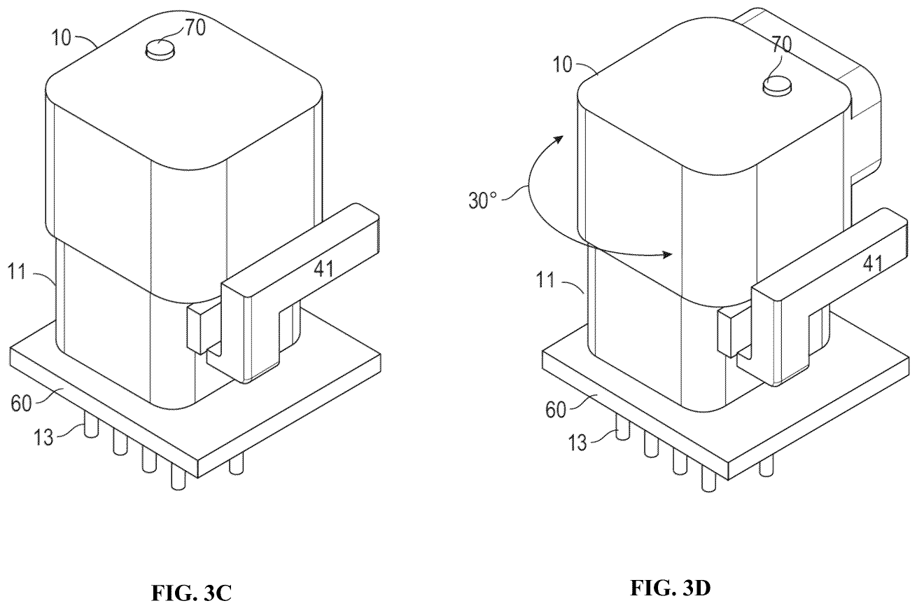

FIG. 3A illustrates an exploded view of the rotatable power socket (200 in FIG. 2) configured for horizontal plug insertion on a printed circuit board (PCB), in accordance with some embodiments of the present disclosure. The exploded view reveals the internal structure and individual components that work in concert to achieve horizontal plug orientation, rotational adjustability, electrical connectivity, and mechanical retention.

The rotatable power socket 200 includes a rotatable socket body (10 in FIG. 2), which houses the internal components and features a socket interface 20 at its front. The socket interface 20 is configured to receive an external power plug (not shown) inserted along a direction substantially parallel to the surface of the PCB, thus enabling horizontal plug insertion that reduces vertical clearance requirements. To aid alignment and prevent improper insertion, the socket interface 20 includes an insertion guide interface 21. An anti-misplug groove 22 is also provided to ensure that the external power plug can only be inserted in a correct and predefined orientation. In some embodiments, the plug alignment structures may further include a directional-restricting groove, which may function similarly to or in conjunction with the anti-misplug groove to constrain the plug to a specific orientation during insertion.

Inside the rotatable socket body, a cable routing track 61 serves as the internal conductor, routing the power cable 61 and the electrical signals from the socket interface 20 to the electrical terminals that connect to the PCB. These electrical terminals are implemented as solder pins 13, which extend downward from the bottom surface of the base structure 11. The solder pins 13 provide both mechanical anchoring and electrical connectivity between the rotatable power socket and the underlying PCB.

The rotatable socket body is coupled to the base structure 11 in a manner that enables rotation about an axis substantially perpendicular to the PCB surface. To provide discrete and stable rotational positioning, a rotational locking assembly is disposed internally between the socket body and the base structure 11. In some embodiments, the rotational locking assembly includes a gear ring 31 affixed to the rotatable socket body, a spring-loaded ball 32 seated in the base structure 11, and a compression spring 33 that biases the ball 32 toward the gear ring 31. As the socket body rotates, the spring-loaded ball 32 engages with detents formed on the gear ring 31, each detent corresponding to a discrete angular position (e.g., every 30° or 45°). The engagement between the ball 32 and detents on the gear ring 31 offers tactile feedback and secure positional locking, preventing unwanted rotation during use. A fixing screw 34 or another form of fastener is used to secure the assembly of the gear ring 31 and the ball 32 in place within the base structure 11.

In some embodiments, to limit the range of rotational motion and prevent over-rotation, an orientation-limiting gear 23 is positioned coaxially with the gear ring 31 and rotates together with the gear ring 31 as part of the rotatable socket body 10. The orientation-limiting gear 23 includes one or more protrusions or tabs distributed along its circumference. These protrusions are configured to interact with physical stop features or cavities formed inside the base structure 11. As the socket body is rotated, the protrusions on the orientation-limiting gear 23 mechanically contact the stop features, thereby defining a bounded rotational arc—e.g., 90° or 180°, depending on the configuration. This mechanical interaction serves as a hard stop that prevents further rotation beyond the intended range, thereby ensuring that internal cables or conductors routed between the socket body and the PCB do not become twisted, strained, or coiled due to excessive rotation.

Externally, the plug retention assembly 41 is mounted on a lateral side of the base structure 11. In the illustrated embodiment, this retention assembly includes a sliding latch that engages the external power plug after insertion, mechanically securing it to prevent loosening or disconnection due to vibration or cable tension. The latch is configured to be manually disengaged by sliding it in the direction opposite the plug insertion direction, enabling easy one-handed removal of the plug when desired.

A cable routing track 61 is also shown, which may be formed within the rotatable socket body. This routing track 61 organizes internal wiring such as power cable 62, ensuring proper spacing and reducing the risk of mechanical interference during socket rotation. The cable routing track 61 also helps manage electromagnetic interference (EMI) and contributes to the structural integrity of the overall assembly.

FIG. 3B illustrates a cross-sectional view of the rotatable power socket (200 in FIG. 2) configured for horizontal plug insertion on a printed circuit board (PCB), in accordance with some embodiments of the present disclosure. This figure illustrates the internal configuration of the rotatable power socket and shows the interaction between key components responsible for the electrical connectivity, rotational adjustability, and mechanical retention.

As mentioned before, the rotatable power socket includes a rotatable socket body 10, which houses the socket interface 20 and is rotatably coupled to a fixed base structure 11. The socket interface 20 is disposed at a side surface (considered as a front face) of the rotatable socket body 10 and is configured to receive an external power plug (not shown) along a direction substantially parallel to the surface of the PCB 60. The socket interface 20 includes an insertion guide interface 21 for plug alignment and an anti-misplug groove 22 to enforce correct plug orientation. A plug retention assembly 41 (corresponding to the latch 41 of FIG. 2), illustrated in its engaged position in this cross-section, is mounted on the lateral side of the base structure 11 and extends into the cavity of the socket body 10 to mechanically secure the plug after insertion.

Inside the rotatable socket body 10, a power cable 62 routes electrical current from the socket interface 20 to the solder pins 13, which extend downward through the base structure 11 for electrical and mechanical connection to the PCB 60. The power cable 62 path is guided and protected by a pair of cable routing tracks 61, which organizes internal wiring to prevent tangling or mechanical interference during rotation.

The rotatable socket body 10 is supported by and configured to rotate relative to the base structure 11 about an axis substantially perpendicular to the PCB 60. A rotational locking assembly is integrated within the rotatable socket body 10 and the base structure 11 to enable controlled angular adjustments and stable positioning. As shown in FIG. 3B, this assembly includes a gear ring 31 affixed to the inner wall of the rotatable socket body 10, such that the gear ring 31 rotates together with the rotatable socket body 10. The gear ring 31 features circumferentially spaced detents that are engaged by a spring-loaded ball 32 housed within the base structure 11. A compression spring 33, held in place by a fixing screw 34, biases the ball 32 (therefore it is also called a spring-loaded ball 32) toward the gear ring 31, causing the spring-loaded ball 32 to snap into the detents and provide discrete angular positions. This mechanism offers tactile feedback and maintains rotational stability during operation.

A cooperating orientation-limiting gear 23 is also disposed adjacent to the gear ring 31 and works in combination with fixed stops or contours within the base structure 11 to define a bounded angular rotation range. This prevents over-rotation that could damage internal wiring or interfere with nearby components. The location and engagement of the orientation-limiting gear 23 ensure rotation within a predefined angular envelope—e.g., 90° or 180°—depending on implementation.

Finally, the LED indicator 70 is mounted on an upper surface of the rotatable socket body 10 and provides visual confirmation of successful plug engagement. The LED 70 may be activated by current sensing, mechanical switching, or other detection mechanisms upon plug insertion and full locking engagement, offering immediate feedback to the user or installer.

In the illustrated embodiment (e.g., FIG. 3A and FIG. 3B), the rotational locking assembly includes a gear ring 31 affixed to the inner wall of the rotatable socket body 10. The gear ring features a series of detents spaced along its outer edge at uniform angular intervals (e.g., every 30° or 45°). These detents are mechanically engaged by a spring-loaded ball 32, which is housed in the base structure 11 and biased outward by a compression spring 33. As the socket body is rotated, the ball 32 snaps into successive detents, providing tactile feedback and stable, discrete rotational positions. As used herein, “affixed” refers to a functional attachment that includes both direct and indirect connections, such as through one or more intermediate structures that transmit rotational motion or mechanical constraint. The gear ring 31 may be connected to the rotatable socket body 10 directly or via coupling elements, provided that the gear ring 31 rotates in concert with the rotatable socket body as part of a unified structure.

In some embodiments, alternative forms of gear rings may be used to implement different locking mechanisms. For example, the gear ring 31 may take the form of a flat circular plate with a plurality of cavities or depressions formed on one of its planar surfaces and distributed in a circular pattern. The spring-loaded ball may be positioned to press axially against this surface, such that it engages with the cavities as the plate rotates. In this configuration, the cavities function as detents, and the interaction between the ball and the surface of the plate provides the same rotational indexing and locking effect.

In other embodiments, the rotational locking mechanism may include a toothed or sawtooth-shaped ring, where each tooth represents a discrete stop. The spring-loaded element may be replaced or supplemented by a flexible tab, cam follower, or resilient finger, which rides over the tooth profile and settles into the valleys between teeth. In yet another variation, a ratcheting mechanism or click-wheel-like structure may be used to provide audible and tactile feedback during rotation.

FIGS. 3C and 3D illustrate two perspective views of the rotatable power socket configured for horizontal plug insertion on a printed circuit board (PCB) 60, in accordance with some embodiments of the present disclosure. These figures illustrate the external appearance, mounting structure, and rotational functionality of the rotatable socket assembly.

As shown in both figures, the rotatable socket body 10 is mounted on the PCB 60 via a base structure that provides mechanical support and electrical connectivity. A plurality of solder pins 13 extend downward from the bottom surface of the socket assembly and penetrate the PCB 60. These solder pins 13 serve as the electrical terminals for delivering power from the external plug—received at the front-facing socket interface—to circuits and components mounted on the PCB 60. The penetration of the solder pins 13 through the PCB 60 also facilitates robust mechanical anchoring and secure electrical contact through conventional through-hole soldering or other mounting techniques.

The rotatable socket body 10 is configured to rotate about an axis substantially perpendicular to the surface of the PCB 60, allowing the socket interface (not visible in the rear view of FIG. 3C, partially visible in the side view of FIG. 3D) to be oriented in multiple directions. In the embodiment illustrated in FIG. 3D, the socket body 10 is shown rotated by approximately 30 degrees relative to its position in FIG. 3C, which corresponds to a different angular position supported by the internal rotational locking assembly (as previously detailed in FIGS. 3A and 3B). This rotational adjustability enables the external power plug to be inserted from different directions, accommodating diverse system layouts, cable routing requirements, and spatial constraints within a chassis or enclosure.

In both views, the LED indicator 70 is positioned on the top surface of the rotatable socket body 10. In addition to providing visual confirmation of successful electrical engagement—such as when the external power plug is fully inserted and securely locked—the placement of the LED indicator 70 may also serve as a visual reference for the orientation of the socket interface. For example, the LED indicator 70 may be located adjacent to the side of the rotatable socket body 10 where the socket interface is positioned, thereby offering users an intuitive visual cue to help identify the direction for plug insertion.

The plug retention assembly 41 is visible on the lateral side of the socket assembly in both figures. As described earlier, the plug retention assembly 41 includes a sliding latch configured to engage and secure the external power plug in place upon insertion, thereby preventing unintentional disconnection due to mechanical shock, vibration, or cable tension. The latch may be disengaged manually to release the plug when desired.

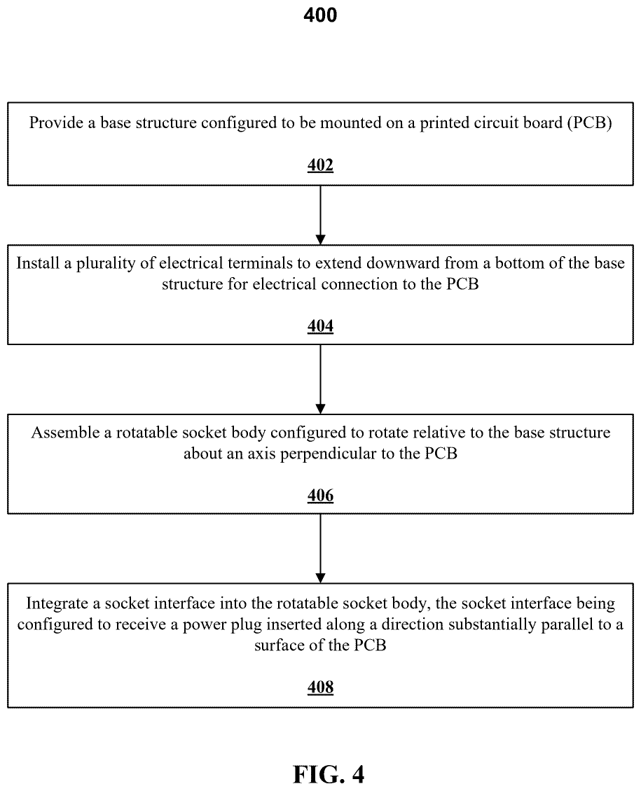

FIG. 4 is a flowchart of an example process 400. In some implementations, one or more process blocks of FIG. 4 may be performed by a manufacturing device.

As shown in FIG. 4, process 400 may include providing a base structure configured to be mounted on a printed circuit board (PCB) (block 402). For example, the manufacturing device may provide a base structure designed to be mounted on a PCB, as described above.

Process 400 may further include installing a plurality of electrical terminals that extend downward from the bottom of the base structure for electrical connection to the PCB (block 404). For example, the manufacturing device may install the terminals as described above to ensure proper electrical and mechanical connection with the PCB.

As further shown in FIG. 4, process 400 may include assembling a rotatable socket body configured to rotate relative to the base structure about an axis substantially perpendicular to the PCB (block 406). For example, the manufacturing device may assemble the rotatable socket body as described above to enable adjustable plug orientation.

Process 400 may also include integrating a socket interface into the rotatable socket body, where the socket interface is configured to receive a power plug inserted along a direction substantially parallel to the surface of the PCB (block 408). For example, the manufacturing device may implement this socket interface design as described above to reduce vertical clearance requirements.

Process 400 may include additional implementations, either individually or in combination, as described below and/or in connection with other processes disclosed herein.

In a first implementation, process 400 further includes assembling a rotational locking assembly between the base structure and the rotatable socket body. The rotational locking assembly comprises a gear ring having a plurality of detents spaced at uniform angular intervals, and a spring-loaded ball biased toward the gear ring and positioned to engage the detents.

In a second implementation, alone or in combination with the first implementation, process 400 further includes attaching a plug retention mechanism to a lateral surface of the base structure. The plug retention mechanism includes a sliding latch configured to engage the external power plug upon insertion.

In a third implementation, alone or in combination with the first and second implementations, process 400 further includes installing an LED indicator on an exterior surface of the rotatable socket body and electrically coupling the LED indicator to one or more of the electrical terminals for activation upon successful plug engagement.

Although FIG. 4 illustrates example blocks of process 400, in some implementations, the process may include additional blocks, fewer blocks, different blocks, or blocks arranged in a different order than depicted. Additionally or alternatively, two or more of the blocks of process 400 may be performed in parallel.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuitry.

When the functions disclosed herein are implemented in the form of software functional units and sold or used as independent products, they can be stored in a processor executable non-volatile computer readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, wherein the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of exemplary methods described herein may be performed, at least partially, by an algorithm. The algorithm may be comprised in program codes or instructions stored in a memory (e.g., a non-transitory computer-readable storage medium described above). Such an algorithm may comprise a machine learning algorithm. In some embodiments, a machine learning algorithm may not explicitly program computers to perform a function but can learn from training data to make a prediction model that performs the function.

The various operations of exemplary methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. A rotatable power socket, comprising:
a base structure configured to be mounted on a printed circuit board (PCB), the base structure comprising a plurality of electrical terminals extending downward from a bottom of the base structure for electrical connection to the PCB;
a rotatable socket body rotatably coupled to the base structure and configured to rotate relative to the base structure about an axis substantially perpendicular to the PCB, the rotatable socket body comprising:
a socket interface configured to receive an external power plug inserted along a direction substantially parallel to the PCB; and
a plug retention assembly configured to retain the external power plug upon insertion; and
a rotational locking assembly disposed between the base structure and the rotatable socket body, the rotational locking assembly configured to provide discrete rotational positions of the rotatable socket body relative to the base structure.

2. The rotatable power socket of claim 1, wherein the rotational locking assembly comprises a gear ring coupled to the rotatable socket body and having a plurality of detents spaced at uniform angular intervals.

3. The rotatable power socket of claim 2, wherein the detents are spaced at 30-degree intervals or 45-degree intervals to define the discrete rotational positions.

4. The rotatable power socket of claim 2, wherein the rotational locking assembly further comprises a spring-loaded ball disposed in the base structure and biased toward the gear ring to engage the plurality of detents.

5. The rotatable power socket of claim 4, wherein the spring-loaded ball is configured in position by a fastener secured within the base structure.

6. The rotatable power socket of claim 1, wherein the plug retention assembly comprises a sliding latch disposed on a lateral side of the base structure and configured to lock the external power plug after insertion.

7. The rotatable power socket of claim 6, wherein the sliding latch is configured to be manually disengaged by sliding in a direction opposite to a direction of the plug insertion.

8. The rotatable power socket of claim 1, further comprising an LED indicator disposed on an exterior surface of the rotatable socket body and configured to emit light in response to electrical engagement with the external power plug.

9. The rotatable power socket of claim 1, further comprising one or more plug alignment structures disposed at or near the socket interface and configured to restrict the insertion orientation of the external power plug.

10. The rotatable power socket of claim 9, wherein the plug alignment structures comprise one or more of insertion guide surface, an anti-misplug groove, or a directional-restricting groove.

11. The rotatable power socket of claim 1, wherein the socket interface is configured to receive a standardized AC power plug or a high-current DC power connector.

12. The rotatable power socket of claim 1, wherein the base structure comprises an internal cable routing track configured to electrically connect the socket interface to the electrical terminals.

13. A power distribution system, comprising:
a printed circuit board (PCB); and
a rotatable power socket mounted on the PCB, the rotatable power socket comprising:
a base structure mounted to the PCB and comprising a plurality of electrical terminals extending into the PCB;
a rotatable socket body coupled to the base structure and rotatable about an axis substantially perpendicular to the PCB, the rotatable socket body comprising a socket interface configured to receive an external power plug inserted along a direction substantially parallel to a surface of the PCB;
a rotational locking assembly configured to provide discrete rotational positions of the rotatable socket body relative to the base structure; and
a plug retention assembly configured to retain the external power plug after insertion.

14. The power distribution system of claim 13, wherein the PCB is part of a motherboard, a backplane, a power distribution board, a communication equipment baseboard, a control board of an AI computing module, or a PCB used in a high-density electronic system.

15. The power distribution system of claim 13, wherein the plug retention assembly comprises a sliding latch disposed on a lateral side of the base structure and configured to lock the external power plug after insertion.

16. The power distribution system of claim 13, wherein the rotatable power socket further comprises an LED indicator disposed on the rotatable socket body and configured to emit light in response to engagement between the external power plug and the electrical terminals of the rotatable power socket.

17. A method of manufacturing a rotatable power socket, comprising:
providing a base structure configured to be mounted on a printed circuit board (PCB);
installing a plurality of electrical terminals to extend downward from a bottom of the base structure for electrical connection to the PCB;
assembling a rotatable socket body configured to rotate relative to the base structure about an axis substantially perpendicular to the PCB; and
integrating a socket interface into the rotatable socket body, the socket interface being configured to receive an external power plug inserted along a direction substantially parallel to a surface of the PCB.

18. The method of claim 17, further comprising:
assembling a rotational locking assembly between the base structure and the rotatable socket body, the rotational locking assembly comprising:
a gear ring having a plurality of detents spaced at uniform angular intervals; and
a spring-loaded ball biased toward the gear ring and positioned to engage the detents.

19. The method of claim 17, further comprising:
attaching a plug retention mechanism to a lateral surface of the base structure, the plug retention mechanism comprising a sliding latch configured to engage the external power plug upon insertion.

20. The method of claim 17, further comprising:
installing an LED indicator on an exterior surface of the rotatable socket body and electrically coupling the LED indicator to one or more of the electrical terminals for activation upon successful plug engagement.
